(19) United States
(12) Patent Application Publication
(10) Pub. No.: US 2024/0210057 A1
(43) Pub. Date: Jun. 27, 2024

(54) HUMIDITY CONTROL DEVICE IN PROCESS SPACE, HUMIDITY CONTROL SYSTEM INCLUDING THE SAME, AND HUMIDITY CONTROL METHOD IN PROCESS SPACE

(71) Applicant: SEMES CO., LTD., Cheonan-si (KR)

(72) Inventors: Yunhwa HONG, Incheon-si (KR); Haneul YOO, Anyang-si (KR); Kiwon HAN, Ansung-si (KR); Junho SEO, Seoul-si (KR)

(73) Assignee: SEMES CO., LTD., Cheonan-si (KR)

(21) Appl. No.: 18/522,675

(22) Filed: Nov. 29, 2023

(30) Foreign Application Priority Data
Dec. 26, 2022 (KR) 10-2022-0185006

(51) Int. Cl. F24F 9/00; F24F 3/14; H01L 21/67; H01L 21/677

(52) U.S. Cl. CPC F24F 9/00; F24F 3/14; H01L 21/67253; H01L 21/67706; H01L 21/67742; F24F 2009/005

(57) ABSTRACT

A humidity control device in a process space allows each process space to satisfy a unique humidity condition and includes an injection module arranged in a second process space maintained at second humidity lower than first humidity within a first process space in which processing for a wafer is performed and configured to inject a gas for forming an air curtain onto a first door through which the wafer enters and exits and which is connected to the second process space, a signal generation module configured to generate an injection signal for the injection module to inject the gas, and an injection control module configured to, when the injection signal is generated, control the injection module to form the air curtain lowering an amount of humidity flowing into the second process space through a space opened by the first door by injecting the gas.

### CROSS-REFERENCE TO RELATED APPLICATION

This application is based on and claims priority under 35 U.S.C. § 119 to Korean Patent Application No. 10-2022-0185006, filed on Dec. 26, 2022, in the Korean Intellectual Property Office, the disclosure of which is incorporated by reference herein in its entirety.

### BACKGROUND

### 1. Field

The disclosure relates to a humidity control device in a process space, which allows each process space to satisfy a unique humidity condition thereof, a humidity control system including the same, and a humidity control method in a process space.

### 2. Description of the Related Art

In general, an ion implantation process, a growth and deposition process, an exposure process, and an etching process are used as processes of manufacturing semiconductor devices on wafers. A semiconductor manufacturing process as described above includes various unit processes that are sequentially repeated.

Therefore, in the semiconductor manufacturing process, wafers may be transferred to various process spaces (process chambers) or semiconductor processing spaces. Here, the respective process spaces need to satisfy unique process conditions (e.g., a process temperature, process humidity, and the like).

### SUMMARY

In particular, each process space from which a wafer is carried out and into which the wafer is placed needs to be maintained at unique process humidity to manufacture a high-quality semiconductor device. Various process spaces may include a high-humidity process space in which a high humidity condition needs to be maintained and a low-humidity process space in which a low humidity condition needs to be maintained. The high-humidity process space and the low-humidity process space may be connected to each other.

Here, when a wafer is transferred from the high-humidity process space to the low-humidity process space or when the wafer is transferred from the low-humidity process space to the high-humidity process space, humidity in the high-humidity process space may flow into the low-humidity process space through an entrance door through which the wafer is transferred. Accordingly, the humidity in the high-humidity process space may become lower, and the humidity in the low-humidity process space may increase.

As described above, when the wafer is transferred along process spaces having different humidity, humidity may move through the entrance door to the process spaces having different humidity, and humidity in the process spaces may be changed. Accordingly, the respective process spaces may not satisfy unique humidity conditions thereof, and as a result, the completeness of the semiconductor manufacturing process may decrease, and thus, a poor-quality product may be manufactured. In particular, in the case of a wafer including a material having high reactivity to humidity, completeness of a semiconductor manufacturing process may be significantly reduced.

Provided are a humidity control device in a process space, which allows each process space to satisfy a unique humidity condition thereof, a humidity control system including the same, and a humidity control method in a process space.

Problems to be solved through embodiments are not limited to the problems described above, and problems not mentioned may be clearly understood by one of ordinary skill in the art to which the embodiments belong from the description and accompanying drawings.

Additional aspects will be set forth in part in the description which follows and, in part, will be apparent from the description, or may be learned by practice of the presented embodiments of the disclosure.

According to an aspect of the disclosure, a humidity control device in a process space includes an injection module arranged in a second process space maintained at second humidity lower than first humidity within a first process space in which processing for a wafer is performed and configured to inject a gas for forming an air curtain onto a first door through which the wafer enters and exits and which is connected to the second process space, a signal generation module configured to generate an injection signal for the injection module to inject the gas, and an injection control module configured to control the injection module to form the air curtain lowering an amount of humidity flowing into the second process space through a space opened by the first door by injecting the gas, when the injection signal is generated.

The injection module may be further configured to inject the gas for forming the air curtain to a side surface of the wafer.

The humidity control device may further include an information processing module configured to determine opening of the first door and generate opening information regarding the opening of the first door when a preparation for transferring the wafer located within the first process space to the second process space is completed, wherein the signal generation module is configured to receive the opening information from the information processing module, and generate the injection signal before the first door is opened.

The injection module may include a first injector and a second injector arranged to face each other and each configured to inject the gas onto the first door.

The injection module may further include a third injector and a fourth injector arranged at locations spaced apart from the first injector and the second injector and configured to inject the gas toward the first process space.

The first injector and the third injector may be further configured to inject the gas onto a second door through which the wafer enters and exits and which is connected to the second process space, and the second injector and the fourth injector may be further configured to inject the gas onto a third door through which the wafer enters and exits and which is connected to the second process space.

The injection control module may be further configured to control a rotation of the injection module to change an injection direction of the injection module.

The injection module may include first to fourth injectors configured to inject the gas toward the first process space, and the injection control module may be further configured to control a rotation of at least one of the first to fourth injectors.

When the first humidity is higher than or equal to preset humidity, the third injector and the fourth injector may rotate toward the first door and inject the gas onto the first door.

When a degree of opening of the first door is opened more than a preset opening amount, the third injector and the fourth injector may rotate toward the first door and inject the gas onto the first door.

The injection control module may be further configured to control an amount of the gas injected by the injection module to be changed.

When the first humidity is higher than or equal to the preset humidity, the injection control module may be further configured to increase the amount of the gas injected by the injection module.

When the degree of opening of the first door is greater than the preset opening amount, the injection control module may be further configured to increase the amount of the gas injected by the injection module.

According to another aspect of the disclosure, a humidity control system includes a first process space in which processing for a wafer is performed and which is maintained at first humidity, a second process space connected to the first process space and maintained at second humidity lower than the first humidity, and a humidity control device in a process space including an injection module installed in the second process space and configured to inject a gas for forming an air curtain onto a first door through which the wafer enters and exits and which is connected to the second process space, a signal generation module configured to generate an injection signal for the injection module to inject the gas, and an injection control module configured to control the injection module to inject the gas to form the air curtain lowering an amount of humidity flowing into the second process space through a space opened by the first door when the injection signal is generated.

The injection module may include a first injector configured to inject the gas onto the first door, a second injector arranged to face the first injector and configured to inject the gas onto the first door, a third injector arranged to face the first injector at a location spaced apart from the second injector and configured to inject the gas onto a second door connected to the first process space, and a fourth injector arranged to face the second injector at a location spaced apart from the first injector and configured to inject the gas onto a third door connected to the first process space.

The injection control module may be further configured to control a rotation of the injection module to change an injection direction of the injection module.

The injection control module may be further configured to control an amount of the gas injected by the injection module to be changed.

According to another aspect of the disclosure, a humidity control method in a process space includes completing a preparation for transferring a wafer located within a first process space to a second process space connected to the first process space, determining opening of a first door connected to the second process space and generating information regarding the opening of the first door, injecting a gas for forming an air curtain onto the first door before the first door is opened, opening the first door, and transferring the wafer to the second process space through a space opened by the first door.

The humidity control method may further include closing the first door, and stopping injecting the gas onto the first door.

The humidity control method may further include performing a processing process for the wafer within the second process space, when the processing for the wafer is completed within the second process space, determining opening of a second door connected to the second process space and generating information regarding the opening of the second door, injecting the gas for forming the air curtain onto the second door before the second door is opened, opening the second door, and carrying out the wafer from the second process space through a space opened by the second door.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a humidity control system according to an embodiment;

FIG. 2 is a schematic side view of a humidity control system according to an embodiment;

FIG. 3 is a block diagram of a humidity control device in a process space, according to an embodiment;

FIGS. 4A to 4D are perspective views illustrating various embodiments of an injection module of a humidity control device in a process space, according to embodiments;

FIGS. 5 to 15 are schematic plan views illustrating an operation process of a humidity control system, according to an embodiment;

FIG. 16 is a flowchart of a humidity control method in a process space, according to an embodiment;

FIG. 17 is flowchart of an example of an operation of forming an air curtain in a humidity control method in a process space, according to an embodiment; and

FIG. 18 is flowchart of another example of an operation of forming an air curtain in a humidity control method in a process space, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

With respect to the terms used to describe the various embodiments, general terms which are currently and widely used are selected in consideration of functions of structural elements in the various embodiments of the disclosure. However, meanings of the terms may be changed according to intention, a judicial precedence, the appearance of new technology, and the like. In addition, in certain cases, a term which is not commonly used can be selected. In such a case, the meaning of the term will be described in detail at the corresponding portion in the description of the disclosure. Therefore, the terms used in the disclosure should be defined based on the meanings of the terms and the descriptions provided herein.

In addition, unless explicitly described to the contrary, the word “comprise” and variations such as “comprises” or “comprising” will be understood to imply the inclusion of stated elements but not the exclusion of any other elements. In addition, the terms “-er”, “-or”, and “module” described herein mean units for processing at least one function and/or operation and can be implemented by hardware components or software components and combinations thereof.

When a component is referred to as being “connected to” another component in the following description, it may be directly connected to the other component, or an intervening component may also be present. Similarly, when one component is referred to as being “on” or “above” another component, it may be directly on the other component, or a third component may be present therebetween. In addition, the structures or sizes of respective components in the drawings are exaggerated for convenience and clarity of description, and portions unrelated to the description are omitted.

The following embodiments relate to a humidity control device in a process space, which allows each process space to satisfy a unique humidity condition thereof, a humidity control system including the same, and a humidity control method in a process space. Embodiments are described below in detail with reference to the accompanying drawings so that one of ordinary skill in the art to which the embodiments belong may easily implement the embodiments. However, the embodiments may be implemented in various different forms and are not limited to the embodiments described herein.

A humidity control system 10 according to an embodiment may be used in a process for processing a semiconductor wafer W. The humidity control system 10 according to an embodiment may include a humidity control device 100 according to an embodiment. Thus, the humidity control system 10 according to an embodiment is described before the humidity control device 100 is described.

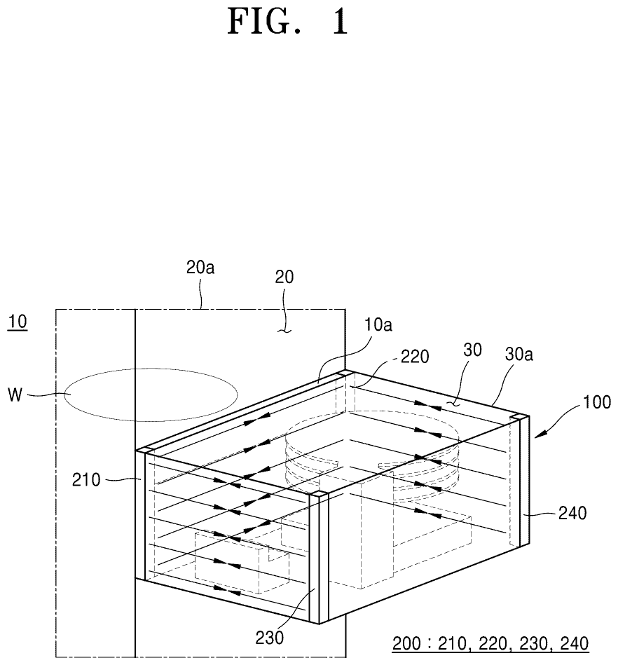

FIG. 1 is a schematic perspective view of a humidity control system according to an embodiment.

The humidity control system 10 according to an embodiment may include a first process space 20, a second process space 30, and the humidity control device 100. However, components of the humidity control system 10 according to an embodiment are not limited thereto, and components according to an embodiment may be added or at least one component may be omitted.

In the first process space 20, work processing may be performed on a wafer W. In an embodiment, a transfer process for the wafer W may be performed in the first process space 20. In other words, the wafer W on which an ion implantation process, a growth and deposition process, an exposure process, and an etching process are performed may stay in the first process space 20 for a while and then be transferred to the second process space 30. The first process space 20 may include a transfer device for transferring the wafer W, and the transfer device may be, for example, a main transfer robot (MTR). The first process space 20 may be arranged inside a first process chamber 20a.

The first process space 20 may be maintained at first humidity. The first humidity may be 30% to 50% on the basis of relative humidity. In detail, the first humidity may be 40%.

The second process space 30 may be connected to the first process space 20, and work processing for the wafer W may be performed in the second process space 30. In an embodiment, in the second process space 30, a buffer process for the wafer W may be performed in which the wafer W stays for a preset time. The wafer W may be cooled while staying in the second process space 30 for a preset time. The second process space 30 may include a cooling device for cooling the wafer W. The second process space 30 may be arranged inside a second process chamber 30a.

The second process space 30 may be maintained at second humidity. The second humidity may be 0.005% to 0.02% on the basis of the relative humidity. In other words, the second humidity may be lower than the first humidity, and the second process space 30 may be maintained at lower humidity than the first process space 20. In detail, the second humidity may be 0.01%.

A first door 10a may be connected to the second process space 30. The first door 10a may be arranged between the first process space 20 and the second process space 30. The wafer W may be transferred from the first process space 20 to the second process space 30 by opening and closing the first door 10a. The first door 10a may be opened and closed, and when the first door 10a is opened or closed, the first process space 20 and the second process space 30 may communicate with each other or may be closed to each other. The first door 10a may also be arranged within the first process space 20 or the second process space 30.

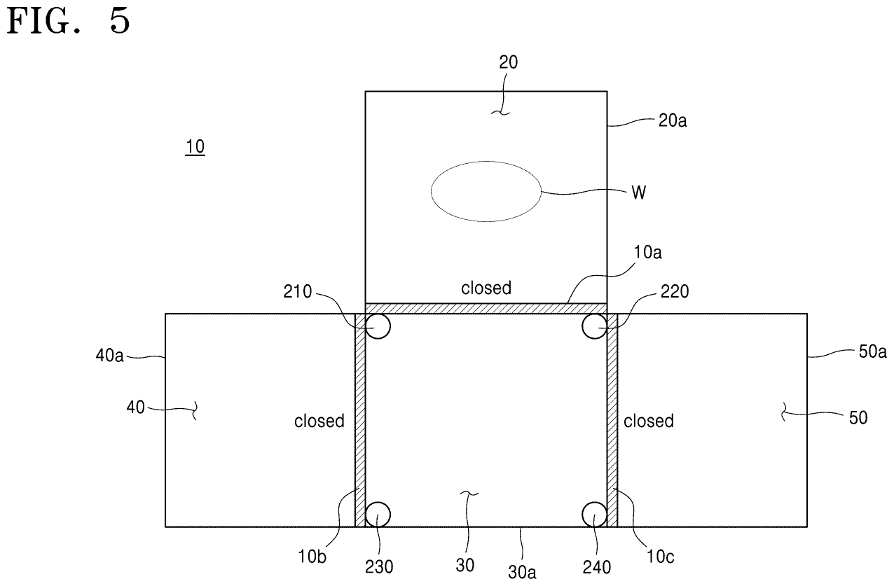

Although not illustrated in FIG. 1, the humidity control system 10 according to an embodiment may further include a third process space 40 (shown in FIGS. 5 to 15) and a fourth process space 50 (shown in FIGS. 5 to 15).

The third process space 40 may be connected to the second process space 30, and work processing for the wafer W may be performed in the third process space 40. In an embodiment, a transfer process for the wafer W may be performed in the third process space 40. In other words, the wafer W on which the buffer process is performed may be carried out from the second process space 30 and transferred to the third process space 40 for a subsequent process. The third process space 40 may include a transfer robot for transferring the wafer W. The third process space 40 may be arranged inside a third process chamber 40a.

The third process space 40 may be maintained at third humidity. The third humidity may be 30% to 50% on the basis of the relative humidity. In other words, the third humidity may be higher than the second humidity, and the third process space 40 may be maintained at higher humidity than the second process space 30. In detail, the third humidity may be 40%.

A second door 10b (shown in FIGS. 5 to 15) may be connected to the second process space 30. The second door 10b may be arranged between the second process space 30 and the third process space 40. The wafer W may be transferred from the second process space 30 to the third process space 40 by opening and closing the second door 10b. When the second door 10b is opened or closed, the second process space 30 and the third process space 40 may communicate with each other or may be closed to each other. The second door 10b may be arranged within the third process space 40 or within the second process space 30.

The fourth process space 50 may be connected to the second process space 30, and work processing for the wafer W may be performed in the fourth process space 50. In an embodiment, a transfer process for the wafer W may be performed in the fourth process space 50. In other words, the wafer W on which the buffer process is performed may be carried out from the second process space 30 and transferred to at least one of the third process space 40 and the fourth process space 50. The fourth process space 50 may include a transfer robot for transferring the wafer W. The fourth process space 50 may be arranged inside a fourth process chamber 50a.

The fourth process space 50 may be maintained at fourth humidity. The fourth humidity may be 30% to 50% on the basis of the relative humidity. In other words, the fourth humidity may be higher than the second humidity, and the fourth process space 50 may be maintained at higher humidity than the second process space 30. In detail, the fourth humidity may be 40%.

A third door 10c (shown in FIGS. 5 to 15) may be connected to the second process space 30. The third door 10c may be arranged between the fourth process space 50 and the second process space 30. The wafer W may be transferred from the second process space 30 to the fourth process space 50 by opening and closing the third door 10c. When the third door 10c is opened or closed, the second process space 30 and the fourth process space 50 may communicate with each other or may be closed to each other. The third door 10c may be arranged within the fourth process space 50 or within the second process space 30.

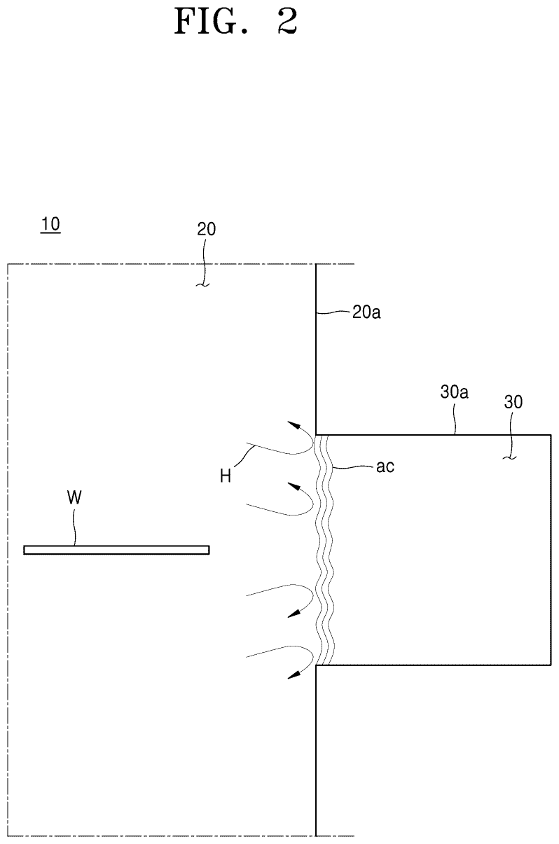

FIG. 2 is a schematic side view of a humidity control system according to an embodiment.

Referring to FIGS. 1 and 2, the humidity control device 100 in a process space according to an embodiment may perform a function of respectively maintaining the first, second, and third process spaces 20, 30, and 40 in unique humidity conditions thereof. Accordingly, the humidity control device 100 in a process space according to an embodiment may include an injection module 200.

The injection module 200 may inject a gas for forming an air curtain ac onto the first door 10a, the second door 10b, and the third door 10c through which the wafer W enters and exits. When the injection module 200 injects the gas, the air curtain ac for lowering an amount of humidity H flowing into the second process space 30 through a space opened by the first door 10a, the second door 10b, and the third door 10c may be formed.

As an example, as shown by arrows in FIG. 1, the injection module 200 may inject the gas for forming the air curtain ac in a horizontal direction with respect to the wafer W. In other words, the injection module 200 may form the air curtain ac by injecting the gas in a transverse direction of the wafer W, rather than injecting the gas from top to bottom or from bottom to top. When the wafer W is transferred to each of the first, second, and third process spaces 20, 30, and 40, the injection module 200 may form the air curtain ac by injecting the gas to a side surface of the wafer W.

In general, when the wafer W is transferred from the first process space 20, which is a high-humidity process space, to the second process space 30, which is a low-humidity process space, the humidity H in the first process space 20 may diffuse or flow into the second process space 30 along a space opened by the first door 10a. When the humidity H flows into the second process space 30, the first process space 20 may not be maintained at the first humidity, the second process space 30 may not be maintained at the second humidity, and thus, the respective process spaces may not satisfy unique process conditions thereof. Accordingly, completeness of the transfer process for the wafer W in the first process space 20 may decrease, and completeness of the buffer process for the wafer W in the second process space 30 may decrease.

According to an embodiment, the air curtain ac may formed on the first door 10a by the gas injected by the injection module 200, and thus, as shown in FIG. 2, the humidity H may not be diffused into the second process space 30. Therefore, a possibility of the humidity H being diffused into the second process space 30 may be fundamentally blocked by the air curtain ac, and thus, the respective process spaces may satisfy unique process conditions thereof. Accordingly, completeness of a semiconductor manufacturing process may be improved, and thus, a possibility of manufacturing a defective product may be reduced.

FIG. 1 illustrates that the injection module 200 includes four injectors (e.g., a first injector 210, a second injector 220, a third injector 230, and a fourth injector 240), but the illustration is an example, and the injection module 200 may include one to three injectors or five or more injectors. In an embodiment, the injection module 200 is described as including the four injectors (e.g., 210, 220, 230, and 240).

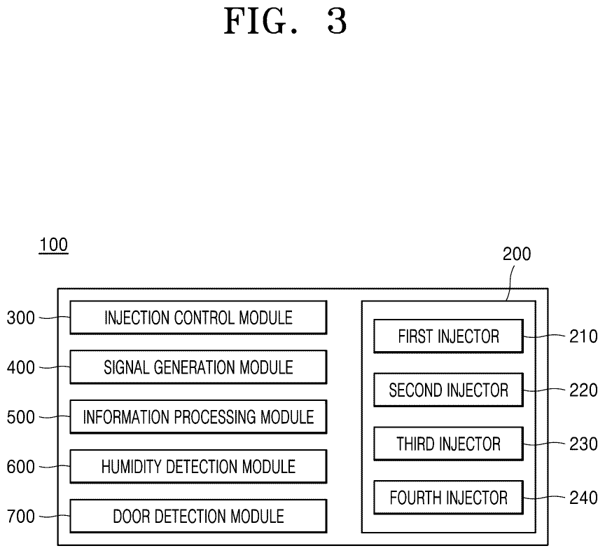

FIG. 3 is a block diagram of a humidity control device in a process space, according to an embodiment.

Referring to FIG. 3, a humidity control device 100 in a process space according to an embodiment may include the injection module 200, an injection control module 300, a signal generation module 400, an information processing module 500, a humidity detection module 600, and a door detection module 700. However, components of the humidity control device 100 in a process space according to an embodiment are not limited thereto, and components according to an embodiment may be added or at least one component may be omitted.

Referring to FIG. 3, the injection module 200 may inject a gas toward the second process space 30. The injection module 200 may form an air curtain ac by injecting the gas toward the second process space 30. The injection module 200 may be installed in the second process space 30 or may be installed between respective process spaces.

As an example, the gas injected by the injection module 200 may be nitrogen (N₂). As another example, the gas injected by the injection module 200 may be oxygen (O₂), or argon (Ar), which is a noble gas.

The injection module 200 may include the first injector 210, the second injector 220, the third injector 230, and the fourth injector 240.

The first injector 210 may be arranged at one location of the second process space 30 to inject the gas toward the second process space 30. The first injector 210 may be arranged between the first door 10a and the second door 10b to inject the gas for forming the air curtain ac toward the second process space 30.

The second injector 220 may be arranged at one location of the second process space 30 at a location spaced apart from the first injector 210 to inject the gas toward the second process space 30. As an example, the second injector 220 and the first injector 210 may be arranged to face each other to together inject the gas for forming the air curtain ac onto the first door 10a. The second injector 220 may be arranged between the first door 10a and the third door 10c.

The third injector 230 may be arranged at one location of the second process space 30 at a location spaced apart from the first injector 210 and the second injector 220 to inject the gas toward the second process space 30. As an example, the third injector 230 may be arranged to face the first injector 210 at a location spaced apart from the second injector 220. The third injector 230 and the first injector 210 may together inject the gas for forming the air curtain ac onto the second door 10b. The third injector 230 may be arranged in the second process space 30 on the opposite side of the first door 10a.

The fourth injector 240 may be arranged at one location of the second process space 30 at a location spaced apart from the first injector 210, the second injector 220, and the third injector 230 to inject the gas toward the second process space 30. As an example, the fourth injector 240 may be arranged to face the second injector 220 at a location spaced apart from the first injector 210. The fourth injector 240 and the second injector 220 may together inject the gas for forming the air curtain ac onto the third door 10c. The fourth injector 240 may be arranged in the second process space 30 on the opposite side of the first door 10a.

As illustrated in FIG. 1, the first injector 210, the second injector 220, the third injector 230, and the fourth injector 240 may inject the gas for forming the air curtain ac in the horizontal direction with respect to the wafer W. In other words, the first injector 210, the second injector 220, the third injector 230, and the fourth injector 240 may form the air curtain ac by injecting the gas in the transverse direction of the wafer W, rather than injecting the gas from top to bottom or from bottom to top. When the wafer W is transferred to each of the first, second, and third process spaces 20, 30, and 40, the first injector 210, the second injector 220, the third injector 230, and the fourth injectors 240 may form the air curtain ac by injecting the gas to a side surface of the wafer W.

In the above description, the injection module 200 may inject the gas into the second process space 30, but the injection is an example, and the injection module 200 may inject the gas between respective process spaces when movement of the humidity H is capable of being blocked by forming the air curtain ac. In other words, the first injector 210 and the second injector 220 may form the air curtain ac by injecting the gas into the first process space 20, o injecting the gas into a space between the first process space 20 and the second process space 30. In addition, the first injector 210 and the third injector 230 may form the air curtain ac by injecting the gas into the third process space 40 or injecting the gas into a space between the second process space 30 and the third process space 40. Also, the second injector 220 and the fourth injector 240 may form the air curtain ac by injecting the gas into the fourth process space 50, or injecting the gas into a space between the second process space 30 and the fourth process space 50.

Referring to FIG. 3, the injection control module 300 may control an operation of the injection module 200. The injection control module 300 may control the injection module 200 to inject the gas for forming the air curtain ac, or may control the injection module 200 to stop injecting the gas. In an embodiment, the injection control module 300 may include at least one processor. The processor may be implemented as an array of a plurality of logical gates, or a combination of a general-purpose microprocessor and a memory that stores programs that may be executed by the microprocessor. In addition, one of ordinary skill in the art to which the present embodiment belongs may understand that the processor may be implemented as other types of hardware.

According to an embodiment, the injection control module 300 may control a rotation of the injection module 200 to change an injection direction of the injection module 200. Accordingly, the injection module 200 may change a location of the air curtain ac formed in the second process space 30.

The injection control module 300 may change an injection direction of at least one of the first injector 210, the second injector 220, the third injector 230, and the fourth injector 240. As an example, the injection control module 300 may rotate the first injector 210 so that the first injector 210 may inject the gas toward the first door 10a or may inject the gas toward the second door 10b. In addition, the injection control module 300 may rotate the second injector 220 so that the second injector 220 may inject the gas toward the first door 10a or may inject the gas toward the third door 10c. Also, the injection control module 300 may rotate the third injector 230 so that the third injector 230 may inject the gas toward the second door 10b or may inject the gas toward the first door 10a. In addition, the injection control module 300 may rotate the fourth injector 240 so that the fourth injector 240 may inject the gas toward the third door 10c or may inject the gas toward the first door 10a.

According to an embodiment, the injection control module 300 may control an amount of gas injected by the injection module 200 to be changed. In an embodiment, the injection control module 300 may control the amount of gas injected by the injection module 200 to be changed according to a magnitude of the first humidity in the first process space 20. In addition, in an embodiment, the injection control module 300 may control the amount of gas injected by the injection module 200 to be changed according to a degree of opening of the first door 10a.

The injection control module 300 may control an amount of gas injected by at least one of the first injector 210, the second injector 220, the third injector 230, the fourth injector 240 to be changed.

Referring to FIG. 3, the signal generation module 400 may generate an injection signal for the injection module 200 to form the air curtain ac by injecting the gas. The injection signal generated by the signal generation module 400 may be provided to the injection control module 300. When the injection signal is provided to the injection control module 300, the injection control module 300 may control the injection module 200 to inject the gas for forming the air curtain ac.

In addition, the signal generation module 400 may also generate an injection stop signal for the injection module 200 to stop injecting the gas. The injection stop signal generated by the signal generation module 400 may be provided to the injection control module 300. When the injection stop signal is provided to the injection control module 300, the injection control module 300 may control the injection module 200 to stop injecting the gas.

The injection signal or the injection stop signal generated by the signal generation module 400 may also be generated by an operation of an operator for an injection of the injection module 200.

Referring to FIG. 3, when a preparation for transferring the wafer W located within the first process space 20 to the second process space 30 is completed, the information processing module 500 may determine opening of the first door 10a and generate opening information related to the opening of the first door 10a. Here, the opening information may be an opened or closed state of the first door 10a, an opening or closing timing of the first door 10a, and an opened or closed time of the first door 10a.

In an embodiment, when the preparation for transferring the wafer W located within the first process space 20 to the second process space 30 is completed, the information processing module 500 may determine whether or not to open the first door 10a to generate the opening information indicating that the first door 10a is opened after a preset time. Here, the signal generation module 400 may receive the opening information from the information processing module 500, and generate the injection signal before the first door 10a is opened (within a preset time).

Accordingly, according to an embodiment, the first injector 210 and the second injector 220 may form the air curtain ac by injecting the gas onto the first door 10a in advance by using the injection signal generated before the first door 10a is opened. Accordingly, a possibility of the humidity H being diffused into the second process space 30 when the first door 10a is opened in advance may be fundamentally blocked, and thus, the second process space 30 may be stably maintained at the second humidity.

In an embodiment, the signal generation module 400 may receive the opening information from the information processing module 500, and also generate the injection signal at the same time when the first door 10a is opened.

According to an embodiment, when processing for the wafer W is completed within the second process space 30, the information processing module 500 may determine opening of at least one of the second door 10b and the third door 10c and generate opening information of at least one of the second door 10b and the third door 10c. Here, the opening information may be opened or closed states of the second door 10b and the third door 10c, opening or closing timings, and opened or closed times.

In an embodiment, when a buffer process for the wafer W is performed within the second process space 30 and the buffer process for the wafer W is completed within the second process space 30, the information processing module 500 may determine whether or not to open at least one of the second door 10b and the third door 10c to generate opening information indicating that the second door 10b or the third door 10c is opened after a preset time. Here, the signal generation module 400 may receive the opening information from the information processing module 500, and generate the injection signal before the second door 10b or the third door 10c is opened (within a preset time).

Accordingly, according to an embodiment, by the injection signal generated before the second door 10b or the third door 10c is opened, the first injector 210 and the third injector 230 may form the air curtain ac by injecting the gas onto the second door 10b in advance, and the second injector 220 and the fourth injector 240 may form the air curtain ac by injecting the gas onto the third door 10c. Accordingly, a possibility of the humidity H being diffused into the second process space 30 when the second door 10b or the third door 10c is opened in advance may be fundamentally blocked, and thus, the second process space 30 may be stably maintained at the second humidity.

In an embodiment, the signal generation module 400 may receive the opening information from the information processing module 500, and also generate the injection signal at the same time when the second door 10b or the third door 10c is opened.

Referring to FIG. 3, the humidity detection module 600 may detect humidity of each of the first, second, third, and fourth process spaces 20, 30, 40, and 50. Here, the humidity detected by the humidity detection module 600 may be relative humidity. Information regarding the humidity of each of the first, second, third, and fourth process spaces 20, 30, 40, and 50, which is detected by the humidity detection module 600, may be provided to the injection control module 300.

Referring to FIG. 3, the door detection module 700 may detect a degree of opening of at least one of the first door 10a, the second door 10b, and the third door 10c. In detail, the door detection module 700 may detect a size of a space opened by the first door 10a, the second door 10b, and the third door 10c. The opening information of the first door 10a, the second door 10b, and the third door 10c, which is detected by the door detection module 700, may be provided to the injection control module 300.

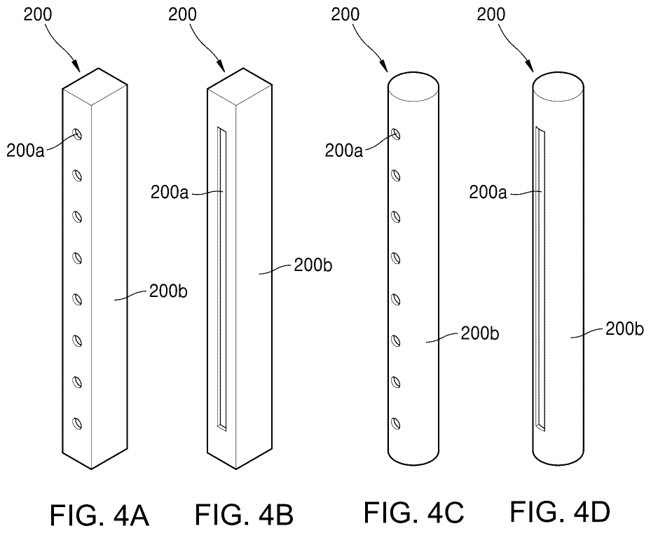

FIGS. 4A to 4D are perspective views illustrating various embodiments of an injection module in a humidity control device in a process space, according to embodiments.

Referring to FIGS. 4A to 4D, an injection module 200 may include an injection hole 200a through which a gas is injected, and an injection main body 200b in which the injection hole 200a is formed.

As an example, as illustrated in FIGS. 4A and 4C, a plurality of injection holes 200a may be formed in the injection main body 200b and spaced apart from one another, and as another example, as illustrated in FIGS. 4B and 4D, the injection hole 200a may extend in a direction in which the injection main body 200b extends.

As an example, as illustrated in FIGS. 4A and 4B, the injection main body 200b may be formed to have a rectangular parallelepiped shape, and as another example, as illustrated in FIGS. 4C and 4D, the injection main body 200b may be formed to have a cylindrical shape.

In an embodiment, each of the first injector 210, the second injector 220, the third injector 230, and the fourth injector 240 may be selected from among injectors illustrated in FIGS. 4A to 4D.

FIGS. 5 to 15 are schematic plan views illustrating an operation process of a humidity control system, according to an embodiment. Hereinafter, an operation process of a humidity control system according to an embodiment is described with reference to FIGS. 5 to 15.

As illustrated in FIGS. 5 to 15, hatching illustrated on the first, second, and third doors 10a, 10b, and 10c may indicate that the first, second, and third doors 10a, 10b, and 10c are closed, and hatching being not illustrated on the first, second, and third doors 10a, 10b, and 10c may indicate that the first, second, and third doors 10a, 10b, and 10c are opened.

FIGS. 5 to 9 illustrate that a wafer W is transferred from a first process space 20 to a second process space 30.

Referring to FIG. 5, a preparation for transferring the wafer W located in the first process space 20 to the second process space 30 may be completed. When processing for the wafer W is completed within the first process space 20, the information processing module 500 may determine opening of the first door 10a and generate opening information regarding the opening of the first door 10a. Accordingly, the signal generation module 400 may receive the opening information from the information processing module 500, and generate an injection signal before the first door 10a is opened.

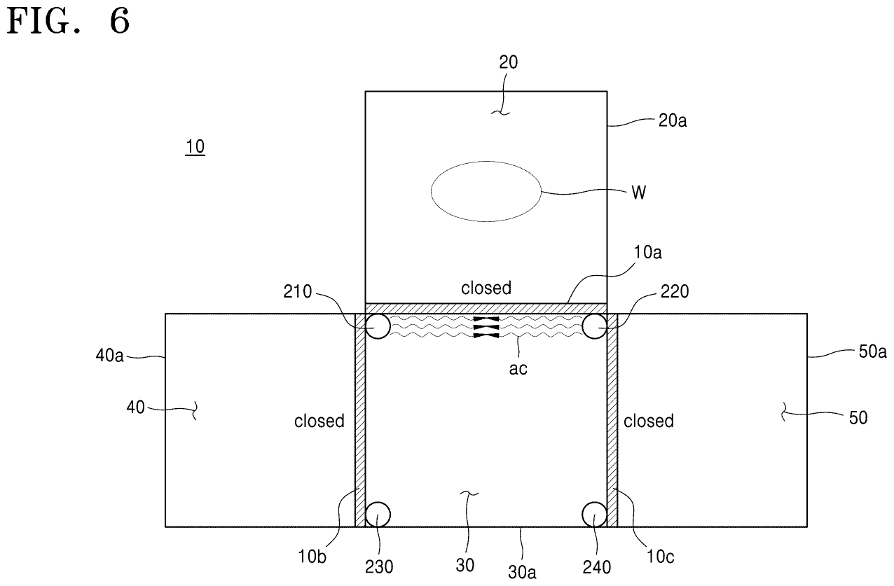

Referring to FIG. 6, a first injector 210 and a second injector 220 may form an air curtain ac by injecting a gas onto the first door 10a before the first door 10a is opened. Accordingly, a possibility of the humidity H being diffused into the second process space 30 when the first door 10a is opened in advance may be fundamentally blocked, and thus, the second process space 30 may be stably maintained at second humidity. In an embodiment, the signal generation module 400 may receive the opening information from the information processing module 500, and generate the injection signal at the same time when the first door 10a is opened.

According to an embodiment, the injection control module 300 may control an amount of gas injected by the injection module 200 to be changed according to a magnitude of the first humidity in the first process space 20.

When the first humidity detected by the humidity detection module 600 is higher than or equal to preset humidity, a difference in humidity between the first process space 20 and the second process space 30 may increase, and thus, a large amount of humidity H may flow into the second process space 30 through a space opened by the first door 10a. To prevent the inflow of a large amount of humidity H, the injection control module 300 may control an amount of gas injected by the first injector 210 and the second injector 220 to increase. When the amount of gas injected by the first injector 210 and the second injector 220 increases, a thickness of the air curtain ac may increase or a density of the air curtain ac may increase. Accordingly, according to an embodiment, even when the first humidity increases, a possibility of the humidity H flowing into the second process space 30 may be lowered. The preset humidity may be set to 60% on the basis of relative humidity.

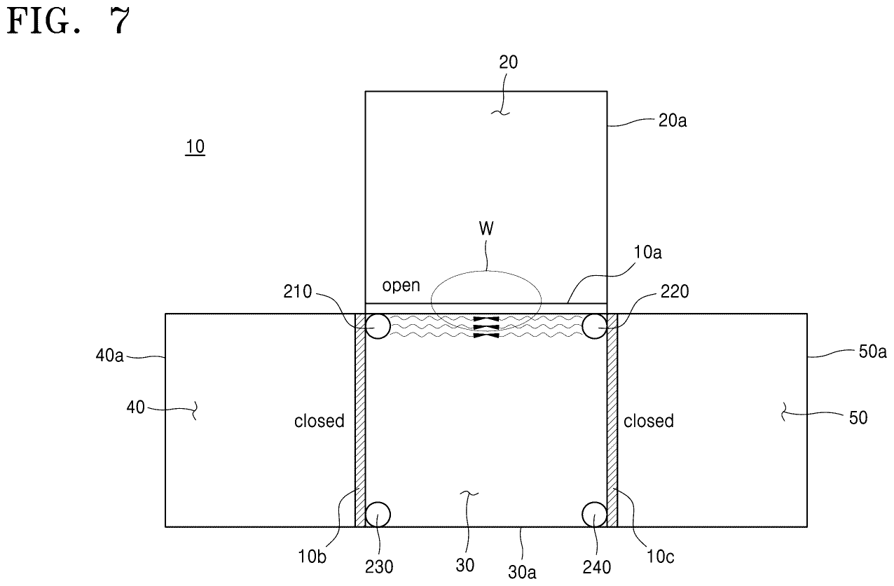

Referring to FIG. 7, the first door 10a may be opened to transfer the wafer W from the first process space 20 to the second process space 30. The air curtain ac may be formed between the first process space 20 and the second process space 30, and thus, the wafer W may pass through the air curtain ac and be transferred to the second process space 30, and the humidity H may not pass through the air curtain ac. Accordingly, the first process space 20 may be maintained at the first humidity, and the second process space 30 may be maintained at second humidity.

As illustrated in FIGS. 1 and 7, the first injector 210 and the second injector 220 may inject the gas for forming the air curtain ac in a horizontal direction with respect to the wafer W. In other words, the first injector 210 and the second injector 220 may form the air curtain ac by injecting the gas in a transverse direction of the wafer W, rather than injecting the gas from top to bottom or from bottom to top. When the wafer W is transferred to the second process space 30, the first injector 210 and the second injector 220 may form the air curtain ac by injecting the gas to a side surface of the wafer W.

According to an embodiment, the injection control module 300 may control the amount of gas injected by the injection module 200 to be changed according to a degree of opening of the first door 10a.

When the degree of opening of the first door 10a detected by the door detection module 700 is opened more than a preset opening amount, a large amount of humidity H may flow into the second process space 30 through a space opened by the first door 10a. To prevent the inflow of a large amount of humidity H, the injection control module 300 may control the amount of gas injected by the first injector 210 and the second injector 220 to increase. Accordingly, according to an embodiment, even when the first door 10a is excessively opened due to a misoperation, an equipment error, or the like, the possibility of humidity H flowing into the second process space 30 may be lowered. The preset opening amount may be set to 110% of a target opening amount.

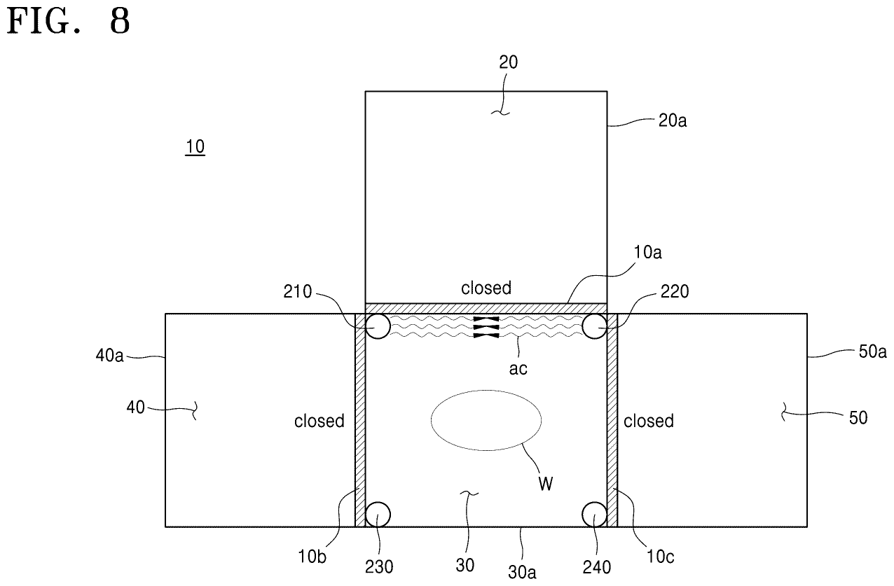

Referring to FIG. 8, when the transfer of the wafer W to the second process space 30 is completed, the first door 10a is closed. When the first door 10a is closed, the signal generation module 400 may generate an injection stop signal and provide the generated injection stop signal to the injection control module 300.

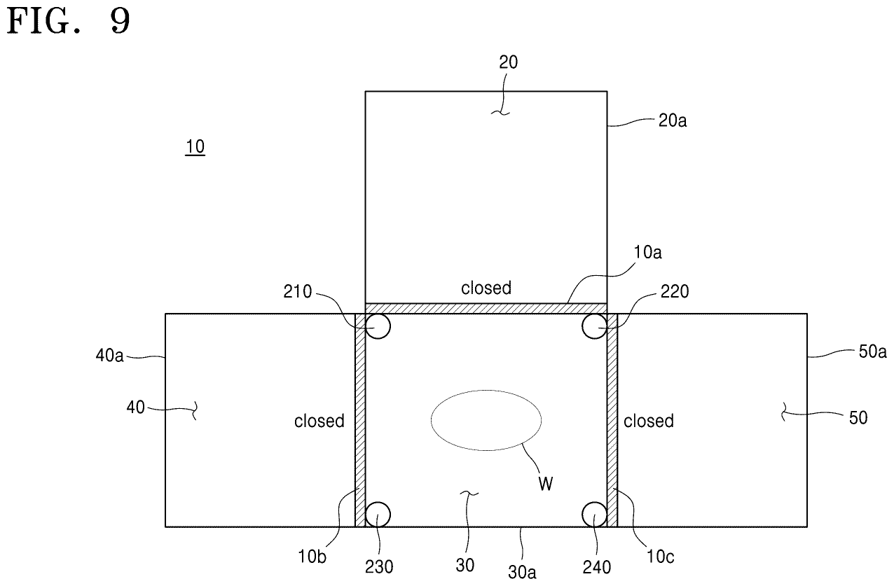

Referring to FIG. 9, when the first door 10a is closed, the injection control module 300 may control the injection module 200 to stop injecting the gas by using the injection stop signal. Accordingly, a process of transferring the wafer W from the first process space 20 to the second process space 30 may be completed, and a buffer process for the wafer W may be performed within the second process space 30.

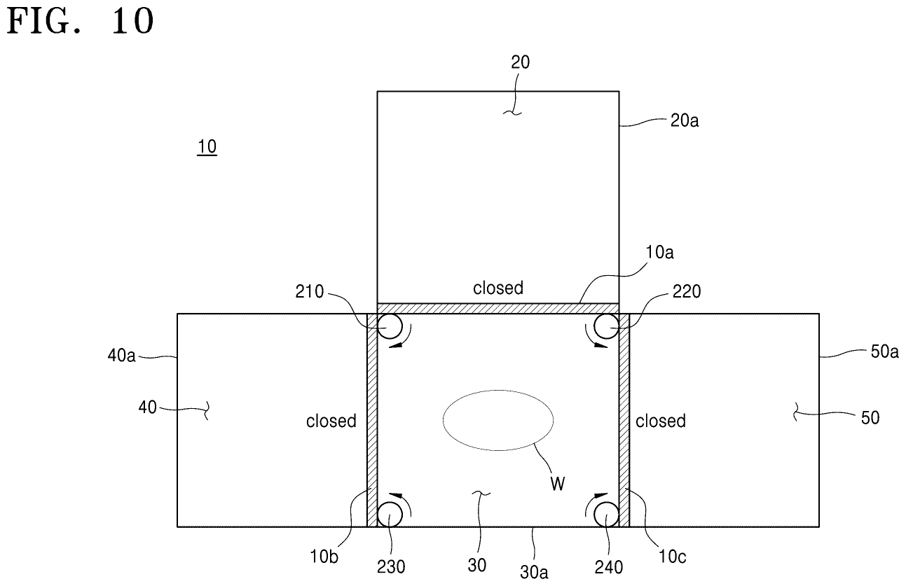

FIGS. 10 to 13 illustrate that a subsequent process is performed in which the wafer W is transferred from the second process space 30 to a third process space 40.

Referring to FIG. 10, a buffer process for the wafer W may be completed in the second process space 30. The completeness of the buffer process may be made automatically after the wafer W stays in the second process space 30 for a preset time, or may be made on the basis of information previously input into the information processing module 500. The information previously input into the information processing module 500 may be information regarding a time for which the wafer W stays within the second process space 30 or a temperature of the wafer W located within the second process space 30. In other words, when the wafer W stays in the second process space 30 for a preset time (e.g., 10 minutes), or when the temperature of the wafer W located within the second process space 30 is less than a preset temperature (e.g., 30° C.), the information processing module 500 may determine that the buffer process for the wafer W is completed.

When the buffer process for the wafer W is completed within the second process space 30, the information processing module 500 may determine opening of at least one of the second door 10b and the third door 10c and generate opening information of at least one of the second door 10b and the third door 10c. Accordingly, the signal generation module 400 may receive the opening information from the information processing module 500, and generate an injection signal before the second door 10b or the third door 10c is opened.

Meanwhile, when the buffer process for the wafer W is completed within the second process space 30, the wafer W may be transferred to the third process space 40 or the fourth process space 50. In an embodiment, when a buffer process for a plurality of wafers W is completed in the second process space 30, each of the plurality of wafers W may be transferred to at least one of the third process space 40 and the fourth process space 50.

According to an embodiment, the injection control module 300 may control a rotation of the injection module 200 to change an injection direction of the injection module 200. As illustrated in FIG. 10, the first injector 210 and the second injector 220 may inject a gas toward the first door 10a, and thus, the injection control module 300 may rotate the first injector 210 toward the second door 10b and rotate the second injector 220 toward the third door 10c. In addition, the injection control module 300 may rotate the third injector 230 toward the second door 10b and rotate the fourth injector 240 toward the third door 10c. Accordingly, an injection hole of the first injector 210 and an injection hole of the third injector 230 may face the second door 10b while facing each other, and an injection hole of the second injector 220 and an injection hole of the fourth injector 240 may face the third door 10c while facing each other.

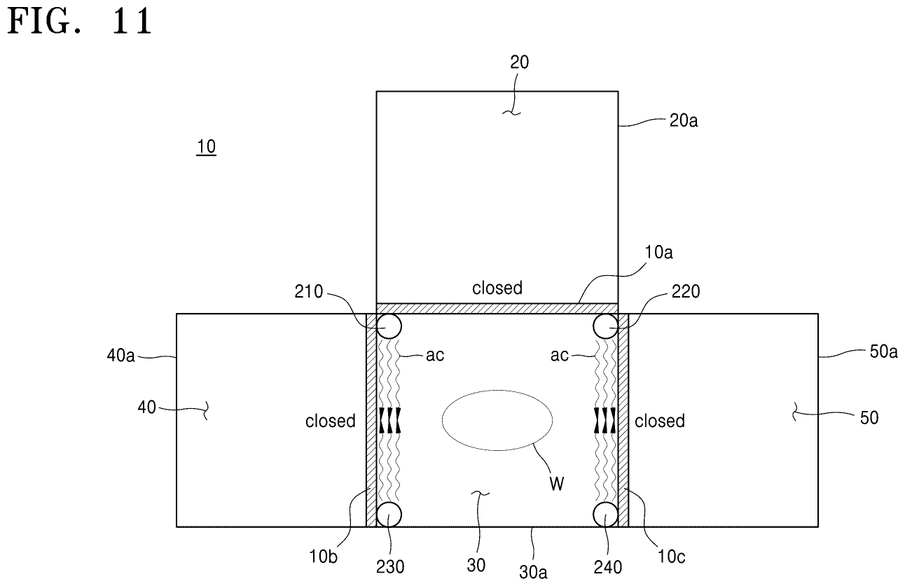

Referring to FIG. 11, the first injector 210 and the third injector 230 may form an air curtain ac by injecting the gas onto the second door 10b before the second door 10b is opened. In addition, the second injector 220 and the fourth injector 240 may form the air curtain ac by injecting the gas onto the third door 10c before the third door 10c is opened. Accordingly, a possibility of humidity H being diffused into the second process space 30 when the second door 10b or the third door 10c is opened in advance may be fundamentally blocked, and thus, the second process space 30 may be stably maintained at second humidity. In an embodiment, the signal generation module 400 may receive opening information from the information processing module 500, and generate an injection signal at the same time when the second door 10b or the third door 10c is opened.

According to an embodiment, the injection control module 300 may control an amount of gas injected by the injection module 200 to be changed according to a magnitude of first humidity of a third process space 40 and a magnitude of fourth humidity of a fourth process space 50.

When the third humidity and the fourth humidity detected by the humidity detection module 600 are higher than or equal to preset humidity, a difference in humidity between the second process space 30 and the third process space 40 and a difference in humidity between the second process space 30 and the fourth process space 50 may increase, and thus, a large amount of humidity H may flow into the second process space 30 through a space opened by the second door 10b and the third door 10c. To prevent the inflow of a large amount of humidity H, the injection control module 300 may control an amount of gas injected by the first injector 210, the second injector 220, the third injector 230, and the fourth injector to increase. Accordingly, according to an embodiment, even when the third humidity and the fourth humidity increase, a possibility of the humidity H flowing into the second process space 30 may be lowered. The preset humidity may be set to 60% on the basis of relative humidity.

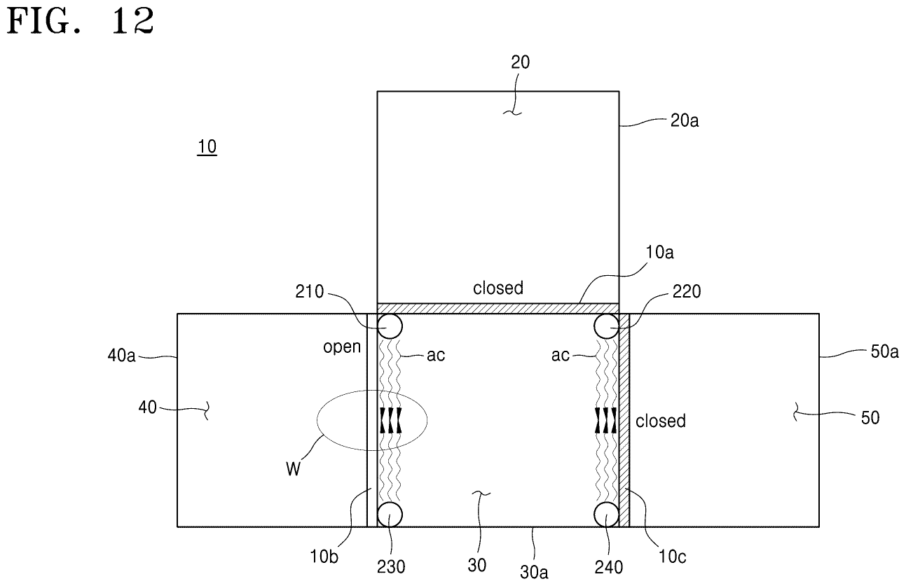

Referring to FIG. 12, the second door 10b may be opened to transfer the wafer W from the second process space 30 to the third process space 40. The air curtain ac may be formed between the second process space 30 and the third process space 40, and thus, the wafer W may pass through the air curtain ac and be transferred to the third process space 30, and the humidity H may not pass through the air curtain ac. Accordingly, the second process space 30 may be maintained at the second humidity.

As illustrated in FIGS. 1 and 12, the first injector 210 and the third injector 230 may inject the gas for forming the air curtain ac in a horizontal direction with respect to the wafer W. In other words, the first injector 210 and the third injector 230 may form the air curtain ac by injecting the gas in a transverse direction of the wafer W, rather than injecting the gas from top to bottom or from bottom to top. When the wafer W is transferred to the third process space 40, the first injector 210 and the third injector 230 may form the air curtain ac by injecting the gas to a side surface of the wafer W.

Meanwhile, although not illustrated, even in an embodiment of opening the third door 10c to transfer the wafer W from the second process space 30 to the fourth process space 50, the air curtain ac may be formed between the second process space 30 and the fourth process space 50. Therefore, the wafer W may pass through the air curtain ac and be transferred to the fourth process space 50, and the humidity H may not pass through the air curtain ac. Accordingly, the second process space 30 may be maintained at the second humidity.

Even in the embodiment described above, as illustrated in FIG. 1, the second injector 220 and the fourth injector 240 may inject the gas for forming the air curtain ac in the horizontal direction with respect to the wafer W. In other words, the second injector 220 and the fourth injector 240 may form the air curtain ac by injecting the gas in the transverse direction of the wafer W, rather than injecting the gas from top to bottom or from bottom to top. When the wafer W is transferred to the fourth process space 50, the second injector 220 and the fourth injector 240 may form the air curtain ac by injecting the gas to the side surface of the wafer W.

According to an embodiment, the injection control module 300 may control an amount of gas injected by the injection module 200 to be changed according to a degree of opening of the second door 10b or the third door 10c.

When the degree of opening of the second door 10b or the third door 10c detected by the door detection module 700 is opened more than the preset opening amount, a large amount of humidity H may flow into the second process space 30 through a space opened by the second door 10b or the third door 10c. To prevent the inflow of a large amount of humidity H, the injection control module 300 may control the amount of gas injected by the first injector 210, the second injector 220, the third injector 230, and the fourth injector 240 to increase. Accordingly, according to an embodiment, even when the second door 10b or the third door 10c is excessively opened due to a misoperation, an equipment error, or the like, the possibility of humidity H flowing into the second process space 30 may be lowered. The preset opening amount may be set to 110% of the target opening amount.

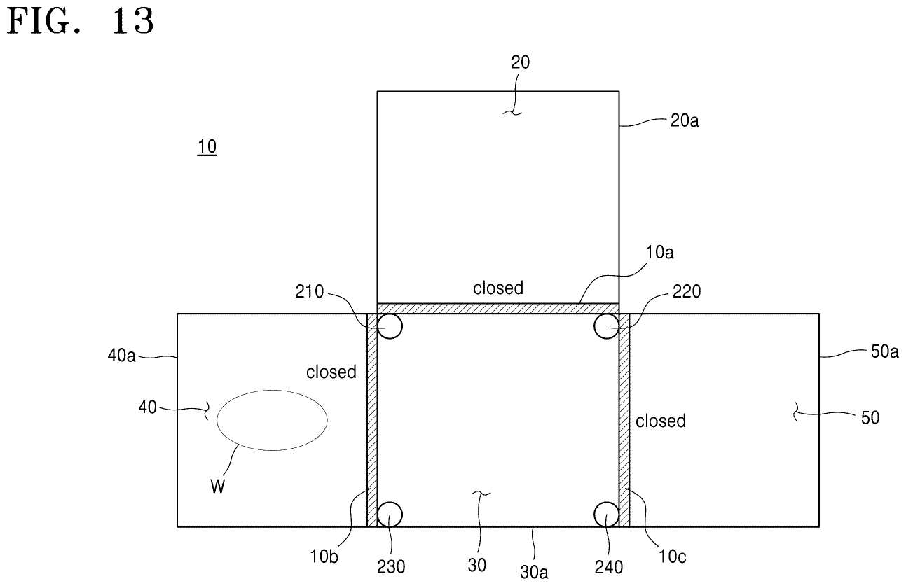

Referring to FIG. 13, when the transfer of the wafer W to the third process space 40 is completed, the second door 10b is closed. When the second door 10b is closed, the signal generation module 400 may generate an injection stop signal and provide the generated injection stop signal to the injection control module 300. The first injector 210 and the third injector 230 may stop injecting the gas by using the injection stop signal. Accordingly, a process of transferring the wafer W from the second process space 30 to the third process space 40 may be completed.

Meanwhile, although not illustrated, when the transfer of the wafer W to the fourth process space 50 is completed, the third door 10c may be closed. When the third door 10c is closed, the signal generation module 400 may generate an injection stop signal and provide the generated injection stop signal to the injection control module 300. The second injector 220 and the fourth injector 240 may stop injecting the gas by using the injection stop signal. Accordingly, a process of transferring the wafer W from the third process space 40 to the fourth process space 50 may be completed.

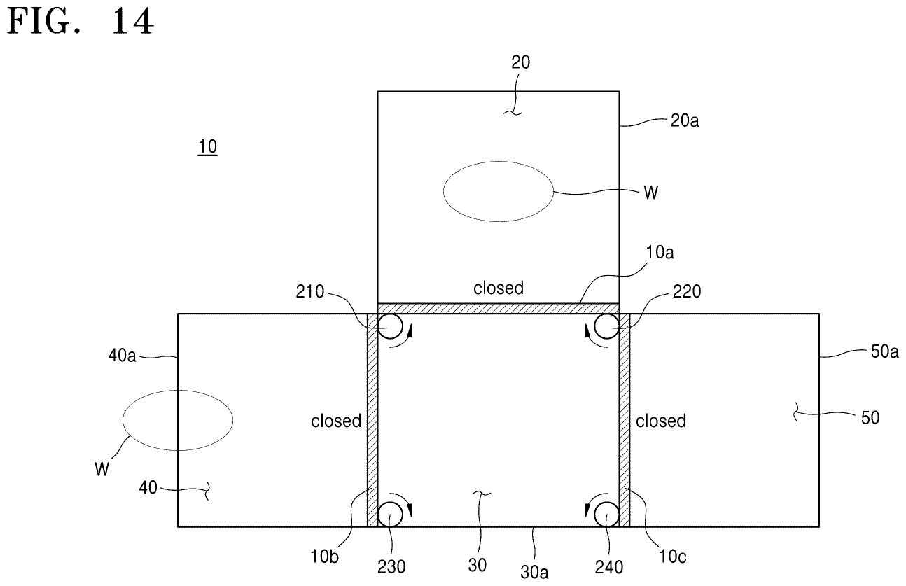

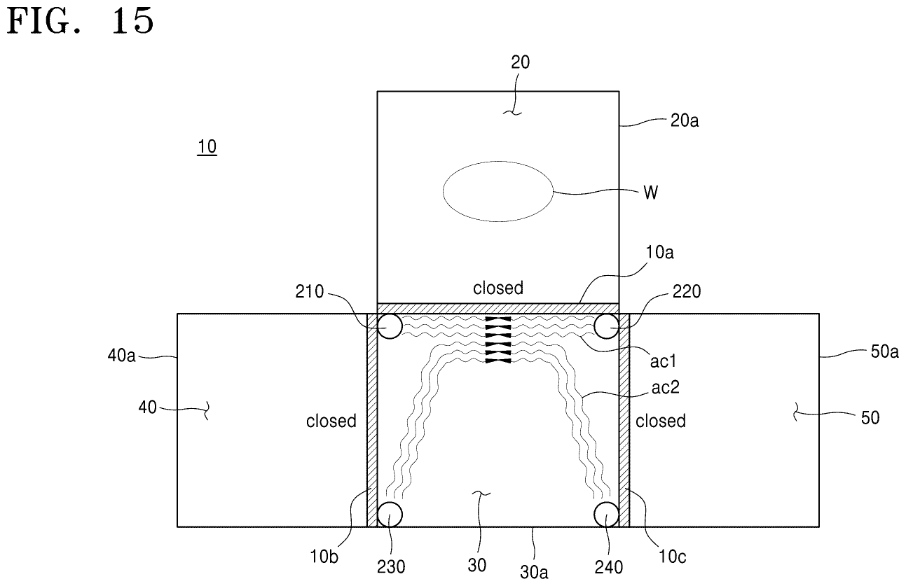

FIGS. 14 and 15 are views illustrating a process of performing a processing process for a new wafer W.

Referring to FIG. 14, a preparation for transferring a new wafer W from a first process space 20 to a second process space 30 may be completed. When the preparation for transferring the wafer W to the second process space 30 is completed, the information processing module 500 may determine opening of a first door 10a and generate opening information of the first door 10a. Accordingly, the signal generation module 400 may receive the opening information from the information processing module 500, and generate an injection signal before the first door 10a is opened.

Here, a first injector 210 may inject a gas onto a second door 10b, and thus, the injection control module 300 may rotate the first injector 210 toward the first door 10a. A second injector 220 may inject the gas onto a third door 10c, and thus, the injection control module 300 may rotate the second injector 220 toward the first door 10a. Accordingly, an injection hole of the first injector 210 and an injection hole of the second injector 220 may face the first door 10a while facing each other.

According to an embodiment, when first humidity is higher than or equal to preset humidity, or when a degree of opening of the first door 10a is greater than or equal to a preset opening amount, a possibility of humidity H flowing into the second process space 30 may be lowered even when the injection control module 300 does not control an amount of gas injected by the injection module 200 to be changed. A description thereof is given below with reference to FIG. 15.

Referring to FIG. 15, when first humidity is higher than or equal to the preset humidity, or when the degree of opening of the first door 10a is greater than or equal to the preset opening amount, the injection control module 300 may rotate the third injector 230 and the fourth injector 240 toward the first door 10a. While an injection hole of the first injector 210, an injection hole of the second injector 220, an injection hole of the third injector 230, and an injection hole of the fourth injector 240 face the first door 10a, the injection control module 300 may operate all of the first injector 210, the second injector 220, the third injector 230, and the fourth injector 240.

Accordingly, as illustrated in FIG. 15, a first air curtain ac1 may be formed by the first injector 210 and the second injector 220, and a second air curtain ac2 may be formed by the third injector 230 and the fourth injector 240. Accordingly, a humidity control system 10 according to an embodiment may form a double air curtain ac in the second process space 30, and thus, a possibility of humidity H flowing into the second process space 30 from the first process space 20 may be significantly lowered.

Although not illustrated, when the third humidity is higher than or equal to the preset humidity, or when the degree of opening of a second door 10b is greater than or equal to the preset opening amount, the injection control module 300 may rotate the second injector 220 and the fourth injector 240 toward the second door 10b. While the injection hole of the first injector 210, the injection hole of the second injector 220, the injection hole of the third injector 230, and the injection hole of the fourth injector 240 face the second door 10b, the injection control module 300 may operate all of the first injector 210, the second injector 220, the third injector 230, and the fourth injector 240. Accordingly, the first air curtain ac1 may be formed by the first injector 210 and the third injector 230, and the second air curtain ac2 may be formed by the second injector 220 and the fourth injector 240.

In addition, when the fourth humidity is higher than or equal to the preset humidity, or when the degree of opening of the third door 10c is greater than or equal to the preset opening amount, the injection control module 300 may rotate the first injector 210 and the third injector 230 toward the third door 10c. While the injection hole of the first injector 210, the injection hole of the second injector 220, the injection hole of the third injector 230, and the injection hole of the fourth injector 240 face the third door 10c, the injection control module 300 may operate all of the first injector 210, the second injector 220, the third injector 230, and the fourth injector 240. Accordingly, the first air curtain ac1 may be formed by the second injector 220 and the fourth injector 240, and the second air curtain ac2 may be formed by the first injector 210 and the third injector 230.

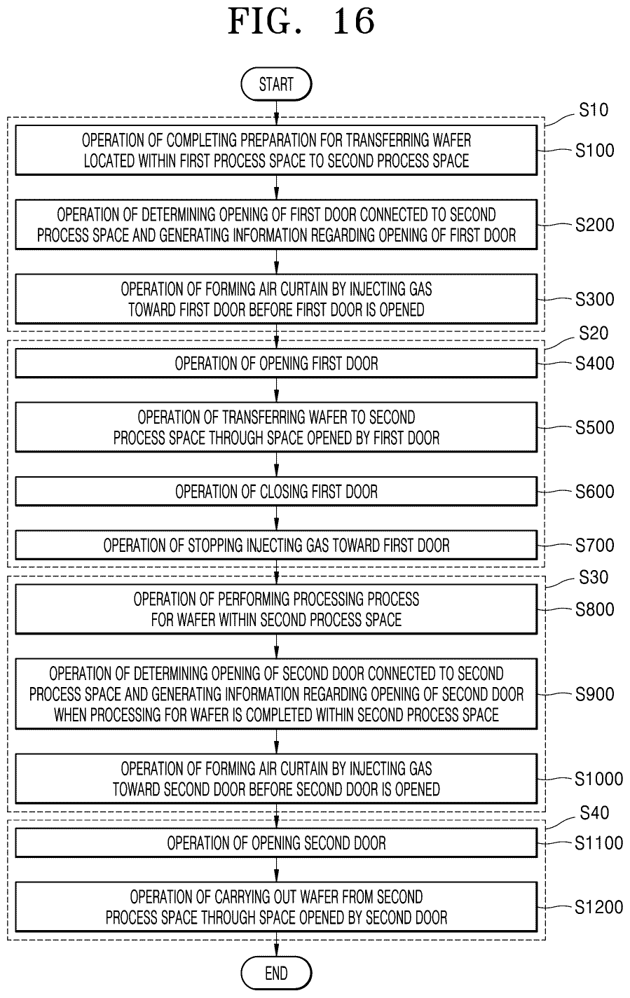

FIG. 16 is a flowchart of a humidity control method in a process space, according to an embodiment. Hereinafter, a humidity control method in a process space according to an embodiment is described with reference to FIG. 16.

The humidity control method in a process space according to an embodiment may include: operation S10 of forming the air curtain ac on the first door 10a to transfer the wafer W located in the first process space 20 to the second process space 30; operation S20 of transferring the wafer W to the second process space 30 and stopping injecting a gas; operation S30 of forming the air curtain ac on the second door 10b or the third door 10c to transfer the wafer W located in the second process space 40 to the third process space 40 or the fourth process space 50; and operation S40 of carrying out the wafer W from the second process space 30.

Operation S10 may include first operation S100 to third operation S300 described below, and operation S20 may include fourth operation S400 to seventh operation S700 described below. In addition, operation S30 may include eighth operation S800 to tenth operation S1000 described below, and operation S40 may include eleventh operation S1100 and twelfth operation S1200 described below. Hereinafter, the respective operations are described in detail.

First operation S100 of completing a preparation for transferring the wafer W located within the first process space 20 to the second process space 30 may be performed. First operation S100 may be automatically performed after the wafer W stays within the first process space 20 for a preset time, or may be performed on the basis of information previously input into the information processing module 500. The information previously input into the information processing module 500 may be information regarding a time for which the wafer W stays within the first process space 20 or a temperature of the wafer W located within the first process space 20. In other words, when the wafer W stays within the first process space 20 for a preset time (e.g., 10 minutes), or when the temperature of the wafer W located within the first process space 20 exceeds a preset temperature (e.g., 50° C.), the information processing module 500 may determine that the preparation for transferring the wafer W to the second process space 30 is completed.

Second operation S200 of determining opening of the first door 10a connected to the second process space 30 and generating information regarding the opening of the first door 10a may be performed. The second operation S200 may be performed by the information processing module 500. When the preparation for transferring the wafer W located within the first process space 20 to the second process space 30 is completed, the information processing module 500 may determine whether or not to open the first door 10a to generate opening information indicating that the first door 10a is opened after a preset time.

Before the first door 10a is opened, third operation S300 of forming the air curtain ac by injecting the gas onto the first door 10a may be performed. Third operation S300 may be performed by the injection control module 300 and the signal generation module 400. In other words, when the signal generation module 400 generates an injection signal, the injection control module 300 may control the injection module 200 to inject the gas. When third operation S300 is performed, the first injector 210 and the second injector 220 may form the air curtain ac on the first door 10a.

In third operation S300, the injection control module 300 may control a rotation of the injection module 200 to change an injection direction of the injection module 200. Accordingly, the injection module 200 may change a location of the air curtain ac formed in the second process space 30. In addition, in third operation S300, the injection control module 300 may control an amount of gas injected by the injection module 200 to be changed. In an embodiment, the injection control module 300 may control the amount of gas injected by the injection module 200 to be changed according to a magnitude of first humidity in the first process space 20. In addition, in an embodiment, the injection control module 300 may control the amount of gas injected by the injection module 200 to be changed according to a degree of opening of the first door 10a.

Fourth operation S400 of opening the first door 10a may be performed. Fourth operation S400 may be performed by a door control module (not shown) that controls an operation of the first door 10a.

Fifth operation S500 of transferring the wafer W to the second process space 30 through a space opened by the first door 10a may be performed. Fifth operation S500 may be performed by a transfer device included in the first process space 20. When fifth operation S500 is performed, the wafer W may be transferred from the first process space 20 to the second process space 30 and located within the second process space 30.

Sixth operation S600 of closing the first door 10a may be performed. Sixth operation S600 may be performed by the door control module.

Seventh operation S700 of stopping injecting the gas onto the first door 10a may be performed. Seventh operation S700 may be performed by the injection control module 300 and the signal generation module 400. In other words, when the signal generation module 400 generates an injection stop signal, the injection control module 300 may control the injection module 200 to stop injecting the gas. When seventh operation S700 is performed, the first injector 210 and the second injector 220 may stop injecting the gas onto the first door 10a.

Eighth operation S800 of performing a processing process for the wafer W within the second process space 30 may be performed. Eighth operation S800 may be an operation in which a buffer process is performed, and may be performed by a cooling device included in the second process space 30. When eighth operation S800 is performed, the wafer W located in the second process space 800 may be cooled.

When processing for the wafer W is completed within the second process space 30, ninth operation S900 of determining opening of the second door 10b connected to the second process space 30 and generating information regarding the opening of the second door 10b may be performed. Ninth operation S900 may be performed by the information processing module 500. When the wafer W stays within the second process space 30 for a preset time (e.g., 10 minutes), or when a temperature of the wafer W located within the second process space 30 is less than or equal to a preset temperature (e.g., 30° C.), the information processing module 500 may determine that the processing for the wafer W is completed, and may determine the opening of the second door 10b and generate the information regarding the opening of the second door 10b.

When the processing for the wafer W is completed within the second process space 30, ninth operation S900 may be performed simultaneously with an operation of determining opening of the third door 10c connected to the second process space 30 and generating information regarding the opening of the third door 10c, or any one operation may be performed first and the other operation may be performed sequentially.

Before the second door 10b is opened, tenth operation S1000 of forming the air curtain ac by injecting the gas onto the second door 10b may be performed. Tenth operation S1000 may be performed by the injection control module 300 and the signal generation module 400. In other words, when the signal generation module 400 generates an injection signal, the injection control module 300 may control the injection module 200 to inject the gas. When tenth operation S1000 is performed, the first injector 210 and the third injector 230 may form the air curtain ac on the second door 10b.

Tenth operation S1000 may be performed simultaneously with an operation of forming the air curtain ac by injecting the gas onto the third door 10c before the third door 10c is opened, or any one operation may be performed first and the other operation may be performed sequentially.

In tenth operation S1000, the injection control module 300 may control a rotation of the injection module 200 to change an injection direction of the injection module 200. In other words, the first injector 210 and the third injector 230 may rotate toward the second door 10b to inject the gas. Accordingly, the first injector 210 and the third injector 230 may form the air curtains ac on the second door 10b. In addition, the second injector 220 and the fourth injector 240 may rotate toward the third door 10c to inject the gas. Accordingly, the second injector 220 and the fourth injector 240 may form the air curtains ac on the third door 10c.

Tenth operation S1000 may include an operation in which the injection control module 300 controls an amount of gas injected by the injection module 200 to be changed according to a magnitude of third humidity in the third process space 40. In other words, when the third humidity is higher than or equal to preset humidity, tenth operation S1000 may include an operation in which the injection control module 300 increases the amount of gas injected by the first injector 210 and the third injector 230. In addition, in an embodiment, tenth operation S1000 may include an operation in which the injection control module 300 controls the amount of gas injected by the injection module 200 to be changed according to a degree of opening of the second door 10b. In other words, when the degree of opening of the second door 10b is greater than or equal to a preset opening amount, in tenth operation S1000, the injection control module 300 may increase the amount of gas injected by the first injector 210 and the third injector 230.

When the third humidity is greater than or equal to the preset humidity, or when the degree of opening of the second door 10b is greater than or equal to the preset opening amount, tenth operation S1000 may also include an operation in which the injection control module 300 rotates the first injector 210, the second injector 220, the third injector 230, and the fourth injector 240 toward the second door 10b. When the operations described above are performed, an injection hole of the first injector 210, an injection hole of the second injector 220, an injection hole of the third injector 230, and an injection hole of the fourth injector 240 may face the second door 10b, and then the injection control module 300 may form a double air curtain ac on the second door 10c by operating all of the first injector 210, the second injector 220, the third injector 230, and the fourth injector 240.

Tenth operation S1000 may include an operation in which the injection control module 300 controls the amount of gas injected by the injection module 200 to be changed according to a magnitude of fourth humidity in the fourth process space 50. In other words, when the fourth humidity is higher than or equal to the preset humidity, in tenth operation S1000, the injection control module 300 may increase the amount of gas injected by the second injector 220 and the fourth injector 240. In addition, in an embodiment, in tenth operation S1000, the injection control module 300 may control the amount of gas injected by the injection module 200 to be changed according to a degree of opening of the third door 10c. In other words, when the degree of opening of the third door 10c is greater than or equal to the preset opening amount, in tenth operation S1000, the injection control module 300 may increase the amount of gas injected by the second injector 220 and the fourth injector 240.

When the fourth humidity is greater than or equal to the preset humidity, or when the degree of opening of the third door 10c is greater than or equal to the preset opening amount, tenth operation S1000 may include an operation in which the injection control module 300 rotates the first injector 210, the second injector 220, the third injector 230, and the fourth injector 240 toward the third door 10c. When the operations described above are performed, the injection hole of the first injector 210, the injection hole of the second injector 220, the injection hole of the third injector 230, and the injection hole of the fourth injector 240 may face the third door 10c, and then the injection control module 300 may form the double air curtain ac on the third door 10c by operating all of the first injector 210, the second injector 220, the third injector 230, and the fourth injector 240.

Eleventh operation S1100 of opening the second door 10b may be performed. Eleventh operation S1100 may be performed by the door control module.

Eleventh operation S1100 may be performed simultaneously with an operation of opening the third door 10c, or any one operation may be performed first and the other operation may be performed sequentially.

Twelfth operation S1200 of carrying out the wafer W from the second process space 30 through a space open by the second door 10b may be performed. Twelfth operation S1200 may be performed by a transfer device included in the third process space 40. When twelfth operation S1200 is performed, the wafer W may be transferred from the second process space 30 to the third process space 40 and located within the third process space 40.

Twelfth operation S1200 may be performed simultaneously with an operation of carrying out the wafer W from the second process space 30 through a space opened by the third door 10c, or any one operation may be performed first and the other operation may be performed sequentially.

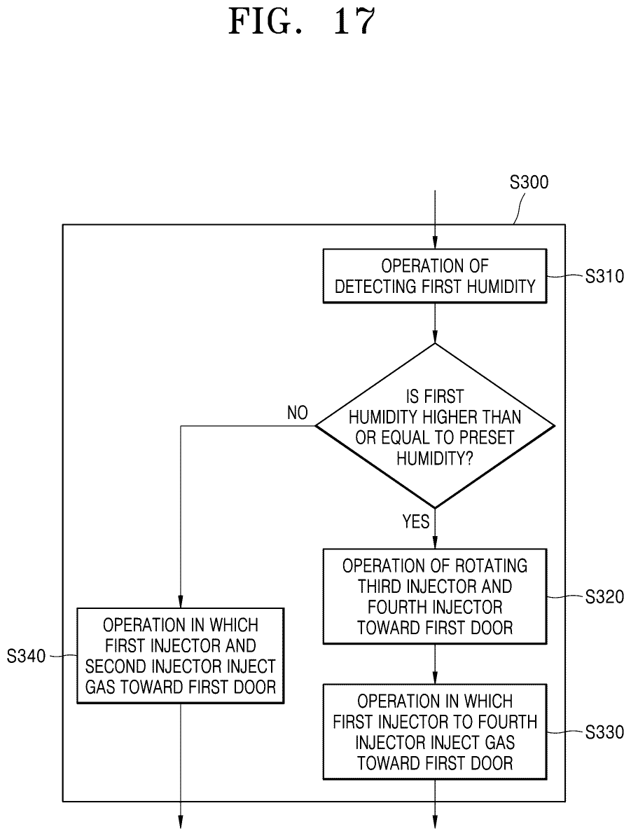

FIG. 17 is flowchart of an example of an operation of forming an air curtain in a humidity control method in a process space, according to an embodiment.

Referring to FIG. 17, third operation S300 may include operation S310 of detecting first humidity. Operation S310 may be performed by the humidity detection module 600.

When the first humidity is higher than or equal to preset humidity, third operation S300 may include operation S320 of rotating the third injector 230 and the fourth injector 240 toward the first door 10a. Operation S320 may be performed by the injection control module 300. Third operation S300 may further include operation S330 in which the first injector 210, the second injector 220, the third injector 230, and the fourth injector 240 inject a gas onto the first door 10a. Operation S320 may be performed by the first injector 210 and the fourth injector 240, and when operation S330 is performed, a double air curtain ac may be formed on the first door 10a.

When the first humidity is less than the preset humidity, third operation S300 may include operation S340 in which the first injector 210 and the second injector 220 inject the gas toward the first door 10a.

In the example shown in FIG. 17, operation S310 of detecting the first humidity may be replaced with an operation of detecting a degree of opening of the first door 10a. In other words, when the degree of opening of the first door 10a is greater than or equal to a preset opening amount, operation S320 of rotating the third injector 230 and the fourth injector 240 toward the first door 10a and operation S330 in which the first door 210, the second injector 220, the third injector 230, and the fourth injector 240 inject the gas toward the first door 10a may be sequentially performed. When the degree of opening of the first door 10a is less than the preset opening amount, operation S340 in which the first injector 210 and the second injector 220 inject the gas toward the first door 10a may be performed.

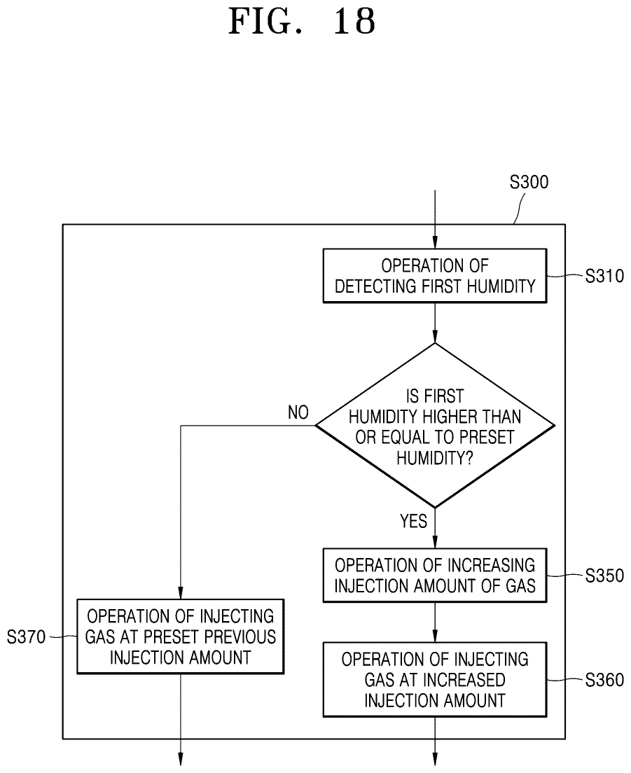

FIG. 18 is flowchart of another example of an operation of forming an air curtain in a humidity control method in a process space, according to an embodiment.

Referring to FIG. 18, third operation S300 may include operation S310 of detecting first humidity. Operation S310 may be performed by the humidity detection module 600.

When the first humidity is higher than or equal to preset humidity, third operation S300 may include operation S350 of increasing an injection amount of gas. Operation S350 may be performed by the injection control module 300. Third operation S300 may further include operation S360 of injecting a gas at the increased injection amount. Operation S360 may be performed by the first injector 210 and the second injector 220.

When the first humidity is less than the preset humidity, third operation S300 may include operation S370 in which the first injector 210 and the second injector 220 inject the gas at a preset previous injection amount.

In the example shown in FIG. 18, operation S310 of detecting the first humidity may be replaced with an operation of detecting a degree of opening of the first door 10a. In other words, when the degree of opening of the first door 10a is greater than or equal to a preset opening amount, operation S320 of increasing the injection amount of gas injected by the first injector 210 and the second injector 220 and operation S350 in which the first injector 210 and the second injector 220 inject the gas at the increased injection amount may be sequentially performed. When the degree of opening of the first door 10a is less than the preset opening amount, operation S370 in which the first injector 210 and the second injector 220 inject the gas at a preset previous injection amount may be performed.

A humidity control device in a process space, a humidity control system including the same, and a humidity control method in a process space according to the spirit of the disclosure may allow each process space to be maintained in a unique process condition thereof by blocking a possibility of humidity flowing into a low-humidity process space.

In addition, the humidity control device in a process space, the humidity control system including the same, and the humidity control method in a process space according to the spirit of the disclosure may lower a possibility of defective products being manufactured by improving completeness of a semiconductor manufacturing process.

Effects according to the spirit of the disclosure are not limited to the above-mentioned effects, and other effects not mentioned will be clearly understood by one of ordinary skill in the art from the following description.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A humidity control device in a process space comprising:
an injection module arranged in a second process space maintained at second humidity lower than first humidity within a first process space in which processing for a wafer is performed, and configured to inject a gas for forming an air curtain onto a first door through which the wafer enters and exits and which is connected to the second process space;
a signal generation module configured to generate an injection signal for the injection module to inject the gas; and
an injection control module configured to control the injection module to form the air curtain lowering an amount of humidity flowing into the second process space through a space opened by the first door by injecting the gas, when the injection signal is generated.

2. The humidity control device of claim 1, wherein the injection module is further configured to inject the gas for forming the air curtain to a side surface of the wafer.

3. The humidity control device of claim 1, further comprising an information processing module configured to determine opening of the first door and generate opening information regarding the opening of the first door when a preparation for transferring the wafer located within the first process space to the second process space is completed, wherein the signal generation module is further configured to receive the opening information from the information processing module, and generate the injection signal before the first door is opened.

4. The humidity control device of claim 1, wherein the injection module comprises a first injector and a second injector arranged to face each other and each configured to inject the gas onto the first door.

5. The humidity control device of claim 4, wherein the injection module further comprises a third injector and a fourth injector arranged at locations spaced apart from the first injector and the second injector and configured to inject the gas toward the first process space.

6. The humidity control device of claim 5, wherein the first injector and the third injector are further configured to inject the gas onto a second door through which the wafer enters and exits and which is connected to the second process space, and the second injector and the fourth injector are further configured to inject the gas onto a third door through which the wafer enters and exits and which is connected to the second process space.

7. The humidity control device of claim 1, wherein the injection control module is further configured to control a rotation of the injection module to change an injection direction of the injection module.

8. The humidity control device of claim 7, wherein the injection module comprises first to fourth injectors configured to inject the gas toward the first process space, and the injection control module is further configured to control a rotation of at least one of the first to fourth injectors.

9. The humidity control device of claim 8, wherein, when the first humidity is higher than or equal to preset humidity, the third injector and the fourth injector rotate toward the first door and inject the gas onto the first door.

10. The humidity control device of claim 8, wherein, when a degree of opening of the first door is greater than a preset opening amount, the third injector and the fourth injector rotate toward the first door and inject the gas onto the first door.

11. The humidity control device of claim 1, wherein the injection control module is further configured to control an amount of the gas injected by the injection module to be changed.

12. The humidity control device of claim 11, wherein, when the first humidity is higher than or equal to the preset humidity, the injection control module is further configured to increase the amount of the gas injected by the injection module.

13. The humidity control device of claim 11, wherein, when the degree of opening of the first door is greater than the preset opening amount, the injection control module is further configured to increase the amount of the gas injected by the injection module.

14. A humidity control system comprising:
a first process space in which processing for a wafer is performed and which is maintained at first humidity;
a second process space connected to the first process space and maintained at second humidity lower than the first humidity; and
a humidity control device in a process space comprising an injection module installed in the second process space and configured to inject a gas for forming an air curtain onto a first door through which the wafer enters and exits and which is connected to the second process space, a signal generation module configured to generate an injection signal for the injection module to inject the gas, and an injection control module configured to control the injection module to inject the gas to form the air curtain lowering an amount of humidity flowing into the second process space through a space opened by the first door when the injection signal is generated.

15. The humidity control system of claim 14, wherein the injection module comprises:
a first injector configured to inject the gas onto the first door;
a second injector arranged to face the first injector and configured to inject the gas onto the first door;
a third injector arranged to face the first injector at a location spaced apart from the second injector and configured to inject the gas onto a second door connected to the first process space; and
a fourth injector arranged to face the second injector at a location spaced apart from the first injector and configured to inject the gas onto a third door connected to the first process space.

16. The humidity control system of claim 14, wherein the injection control module is further configured to control a rotation of the injection module to change an injection direction of the injection module.

17. The humidity control system of claim 14, wherein the injection control module is further configured to control an amount of the gas injected by the injection module to be changed.

18. A humidity control method in a process space comprising:
completing a preparation for transferring a wafer located within a first process space to a second process space connected to the first process space;
determining opening of a first door connected to the second process space and generating information regarding the opening of the first door;
injecting a gas for forming an air curtain onto the first door before the first door is opened;
opening the first door; and
transferring the wafer to the second process space through a space opened by the first door.

19. The humidity control method of claim 18, further comprising:
closing the first door; and
stopping injecting the gas onto the first door.

20. The humidity control method of claim 19, further comprising:
performing a processing process for the wafer within the second process space;
when the processing for the wafer is completed within the second process space, determining opening of a second door connected to the second process space and generating information regarding the opening of the second door;
injecting the gas for forming the air curtain onto the second door before the second door is opened;
opening the second door; and
carrying out the wafer from the second process space through a space opened by the second door.
